(19) United States
(12) Patent Application Publication
(10) Pub. No.: US 2012/0220087 A1
(43) Pub. Date: Aug. 30, 2012

(54) VARIABLE RESISTANCE MEMORY DEVICES AND METHODS OF MANUFACTURING THE SAME

(75) Inventor: Kiseok SUH, HWASEONG-SI (KR)

(73) Assignee: SAMSUNG ELECTRONICS CO., LTD., SUWON-SI (KR)

(21) Appl. No.: 13/396,658

(22) Filed: Feb. 15, 2012

(30) Foreign Application Priority Data
Feb. 24, 2011 (KR) 10-2011-0016637

(51) Int. Cl. H01L 21/8239

(52) U.S. Cl. 438/238; 257/E21.645

(57) ABSTRACT

A variable resistance memory device includes a substrate having a cell array region and a peripheral circuit region, an epitaxial semiconductor layer on the cell array region and the peripheral circuit region, and a peripheral transistor whose channel region is constituted by the epitaxial semiconductor layer on the peripheral circuit region. The peripheral transistor is formed by forming a gate electrode structure on the epitaxial semiconductor layer, and implanting impurities into the epitaxial semiconductor layer to form a source/drain region.

### PRIORITY STATEMENT

A claim of priority under 35 U.S.C. §119 is made to Korean Patent Application No. 10-2011-0016637, filed on Feb. 24, 2011, the entire contents of which are hereby incorporated by reference.

### BACKGROUND

The inventive concept relates to variable resistance memory devices and to methods of manufacturing the same.

Semiconductor devices may be classified into memory devices and logic devices. The memory devices store data. In general, the memory devices may be largely divided into volatile memory devices and nonvolatile memory devices. Volatile memory devices, e.g., Dynamic Random Access Memory (DRAM) devices and Static Random Access Memory (SRAM) devices, lose their stored data once power is no longer supplied to the devices. Nonvolatile memory devices, e.g., Programmable ROMs (PROMs), Erasable PROMs (EPROMs), Electrically EPROMs (EEPROMs) and flash memory devices, retain their stored data even once the power being supplied to the devices has been turned off.

Additionally, next generation semiconductor memory devices such as Ferroelectric Random Access Memory (FRAM), Magnetic Random Access Memory (MRAM), and Phase-Change Random Access Memory (PRAM) devices are in development to meet the demand for high performance semiconductor memory devices which have relatively low power consumptions. These next generation semiconductor memory devices employ materials whose resistances vary according to the amount of current or voltage supplied/applied and maintain their resistance even the current or voltage supplied/applied thereto has been interrupted or cutoff.

### SUMMARY

According to an aspect of the inventive concept, there is provided a method of manufacturing a variable resistance memory device, comprising: providing a substrate having a cell array region and a peripheral circuit region, using an epitaxial process in forming a semiconductor layer on the cell array region and the peripheral circuit region such that the semiconductor layer is an epitaxial semiconductor layer, and forming a peripheral transistor constituted by part of the epitaxial semiconductor layer on the peripheral circuit region.

According to another aspect of the inventive concept, there is provided a method of manufacturing a variable resistance memory device, comprising: providing a substrate having a cell array region and a peripheral circuit region, forming structures of semiconductor material on the cell array region and forming an active region of semiconductor material on the peripheral circuit region including by epitaxially growing crystalline material simultaneously on the cell array region and the peripheral circuit region, forming variable resistor elements on the structures of semiconductor material on the cell array region, and forming a peripheral transistor at the active region.

According to still another aspect of the inventive concept, there is provided a variable resistance memory device comprising: a substrate having a cell array region and a peripheral circuit region, selecting devices in the form of diodes, Metal Oxide Semiconductor (MOS) transistors, or bipolar transistors on the cell array region, first conductive lines extending below the selecting devices and electrically connected to the selecting devices, variable resistance memory elements on the selecting devices, and a peripheral transistor on the peripheral circuit region, wherein the peripheral transistor comprises an epitaxial pattern of semiconductor material on the peripheral circuit region, and the top surface of the epitaxial pattern on the peripheral circuit region is located at a level above the level of the top surfaces of the first conductive lines.

### BRIEF DESCRIPTION OF THE DRAWINGS

In the drawings:

FIG. 1 is a circuit diagram of a memory cell array of a variable resistance memory device according to the inventive concept;

FIG. 2 is a plan view of a general layout of a cell array that may be adopted by various embodiments of a variable resistance memory device according to the inventive concept;

FIGS. 3 through 9 are each a sectional view in the direction of lines A-A′, B-B′, and C-C′ of FIG. 2 and together illustrate a first embodiment of a variable resistance memory device and a method of manufacturing the same according to the inventive concept;

FIGS. 10 through 14 are each a sectional view in the direction of lines A-A′, B-B′, and C-C′ of FIG. 2 and together illustrate a second embodiment of a variable resistance memory device and a method of manufacturing the same according to the inventive concept; and

FIG. 15 is a block diagram of a memory system employing a variable resistance memory device according to the inventive concept.

### DETAILED DESCRIPTION OF THE PREFERRED EMBODIMENTS

Various embodiments and examples of embodiments of the inventive concept will be described more fully hereinafter with reference to the accompanying drawings. In the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, like numerals are used to designate like elements throughout the drawings.

Furthermore, spatially relative terms, such as “upper,” and “lower” are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use. In addition, the terms “top” or “bottom” as used to describe a surface or region generally refer not only to the orientation depicted in the drawings but to the fact that the surface or boundary is the uppermost or bottommost surface or boundary in the orientation depicted, as would be clear from the drawings and context of the written description.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes. The term “substrate” will generally refer to that portion of the device that is non-active and forms the base of the device and may thus exclude regions that are doped, for example, again as the context makes clear. The term “pattern” will generally refer to an element or feature that has been formed as the result of a patterning process (e.g., an etching or damascene process), i.e., an element or feature formed as the result of the patterning of some particular layer.

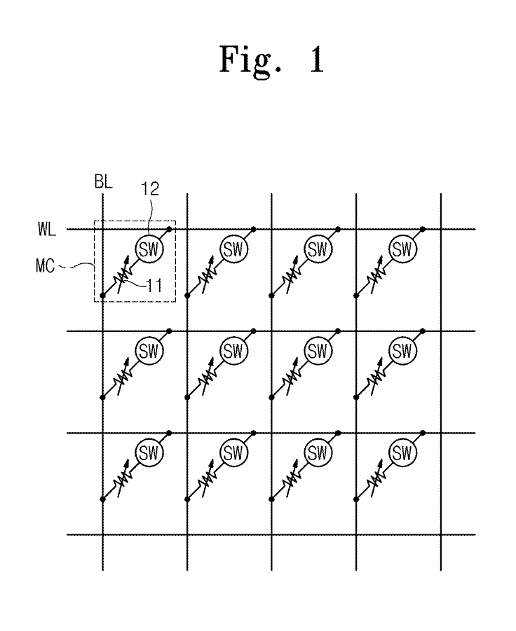

A circuit of a memory cell array of a variable resistance memory device according to the inventive concept will now be described with reference to the diagram of FIG. 1.

The memory cell array has a plurality of memory cells MC arranged in a matrix. Each memory cell MC includes a variable resistance element 11 and a selecting element 12. The variable resistance element 11 and the selecting element 12 are interposed between a bit line BL and a word line WL.

In an example of this embodiment, the state of the variable resistance element 11 depends on the amount of current supplied through the bit line BL. The selecting element 12 is connected between the variable resistance element 11 and the word line WL to control the current supplied to the variable resistance element 11 based on the voltage of the word line WL. To this end, the selecting element 12 may be a diode, a Metal Oxide Semiconductor (MOS) transistor, or a bipolar transistor.

Also, an example of the variable resistance element 11 that will be used in the following description is a phase change memory device. A phase change memory device is made of phase change material that can be converted between an amorphous state (in which its resistance is relatively high) and a crystalline state (in which its resistance is relatively low) by being heated to a certain temperature or by being allowed to cool for a certain amount of time. The amorphous state may be a SET state and the crystalline state may be a RESET state. In this respect, the phase change memory device also has a lower electrode for heating the phase change material. Specifically, the lower electrode generates Joule's heat according to the amount of current supplied through the lower electrode, to thereby heat the phase change material.

However, the inventive concept is not limited to the use of phase change memory devices as the variable resistance elements 11. Rather, other known types of variable resistance elements may be used instead.

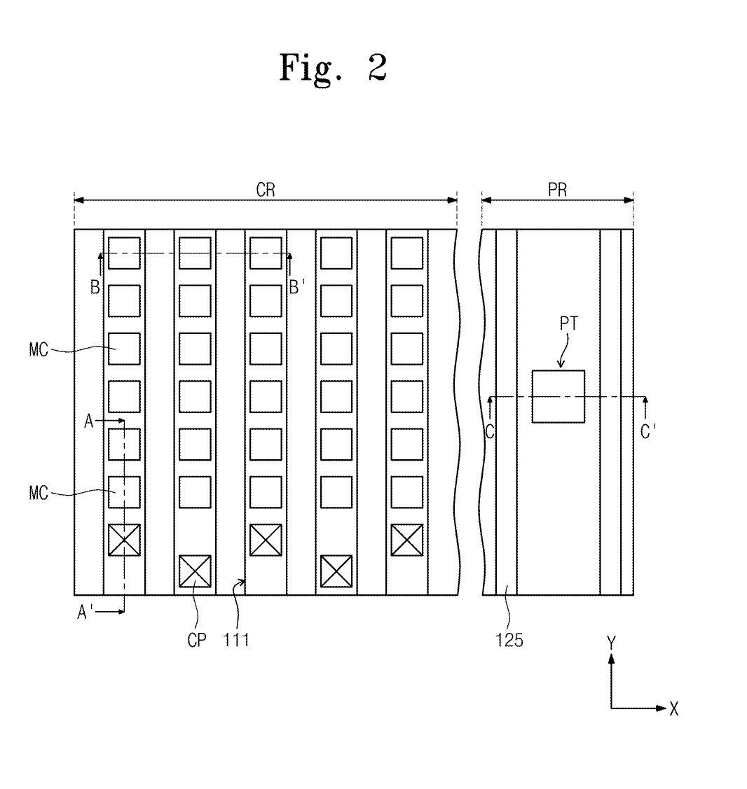

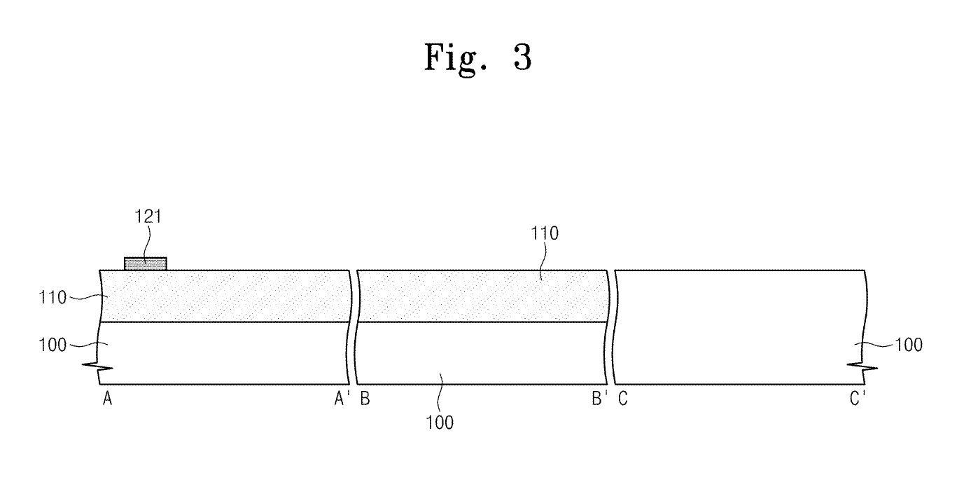

A layout of a cell array that may be adopted by variable resistance memory devices according to the inventive concept will now be described with reference to FIG. 2, and a first embodiment of a variable resistance memory device and of a method of manufacturing the same will be described with reference to FIGS. 3 through 9.

Referring to FIGS. 2 and 3, a substrate 100 including a cell array region CR and a peripheral circuit region PR is provided. The substrate 100 is semiconductor based and may be a silicon, Silicon On Insulator (SOI), SiGe, Ge, or GaAs substrate. In an example of the present embodiment, the substrate 100 is a p-type silicon substrate.

A first impurity region 110 is formed in the cell array region CR. The conductivity type of the first impurity region 110 is different from that of the substrate 100. In the example of the present embodiment, the first impurity region 110 is formed by forming an ion implantation mask (not shown) on the substrate 100 to cover the peripheral circuit region PR, and then doping the substrate 100 with n-type impurity ions (at a high concentration). However, the first impurity region 110 may be formed in the peripheral circuit region PR. In either case, a thermal treatment may be subsequently performed to cure defects caused by the ion implantation process.

Next, an etch stop layer 121 is provided on the first impurity region 110. The etch stop layer 121 is formed of a material different than that of the substrate 100. For example, the etch stop layer 121 may comprise silicon nitride or silicon oxynitride.

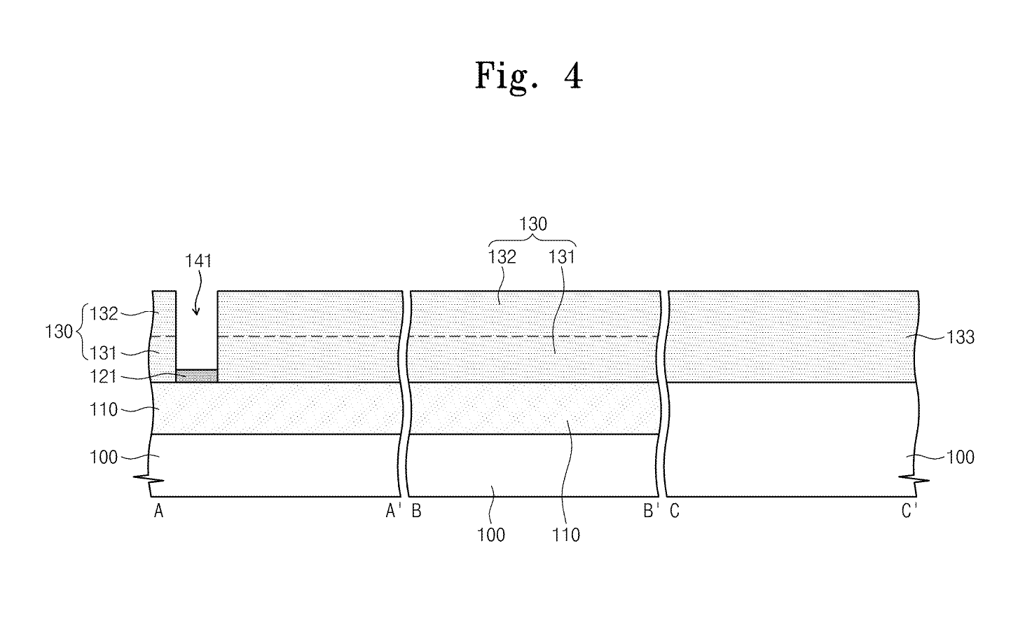

Referring to FIGS. 2 and 4, an epitaxial semiconductor layer is formed on the substrate 100. The epitaxial semiconductor layer may include a first epitaxial semiconductor layer 130 on the cell array region CR and a second epitaxial semiconductor layer 133 on the peripheral circuit region PR. The first and second epitaxial semiconductor layers 130 and 133 may be simultaneously formed. For example, the first and second epitaxial semiconductor layers 130 and 133 may be formed by MetalOrganic Chemical Vapor Deposition (MOCVD), Molecular Beam Epitaxy (MBE), Liquid Phase Epitaxy (LPE), or Vapor Phase Epitaxy (VPE).

At this time, a lower impurity region 131 having a conductivity type different than that of the substrate 100 is formed at the lower part of the first epitaxial semiconductor layer 130. For example, the lower impurity region 131 may be formed as the result of the diffusion of impurity ions from the first impurity region 110 into the lower part of the epitaxial semiconductor layer 130 as the epitaxial semiconductor layer 130 is being formed. Alternatively, the lower impurity region 131 may be formed by an in-situ doping process or an ion implantation process.

Also, at this time, an upper impurity region 132 having the same conductivity type as the substrate 100 may be formed at the upper port of the first epitaxial semiconductor layer 130. Thus, in the example of the present embodiment, the upper impurity region 132 is a p-type impurity region. The upper impurity region 132 may be formed through an ion implantation process or an in-situ doping process.

The first epitaxial semiconductor layer 130 does not form on the etch stop layer 121. Thus, in the illustrated embodiment, a first opening 141 is defined on the etch stop layer 121 as the first epitaxial semiconductor layer 130 grows. In another example of this embodiment, an insulation pattern (not shown) is provided on the etch stop layer 121 before the epitaxial semiconductor layer 130 is formed (in which case no opening in the first epitaxial semiconductor layer is formed on the etch stop layer 121).

The second epitaxial semiconductor layer 133 may be formed by epitaxially growing a layer of material on the peripheral circuit region PR, and implanting impurity ions into the upper part only of the expitaxially grown layer (i.e., while leaving the lower part of the epitaxially grown layer as it is).

In any case, the conductivity type of the second epitaxial semiconductor layer 133 depends on the type of transistors to be provided for the finalized device. For example, in the case in which a Complementary Metal Oxide Semiconductor (CMOS) transistor is provided in the peripheral circuit region PR, the second epitaxial semiconductor layer 133 may be used as an active region of an NMOS transistor and/or a PMOS transistor. Therefore, the second epitaxial semiconductor layer 133 may be of the same or different conductivity type as the substrate 100. In this example, as applied to the present embodiment, the second epitaxial semiconductor layer 133 has a p-type of conductivity.

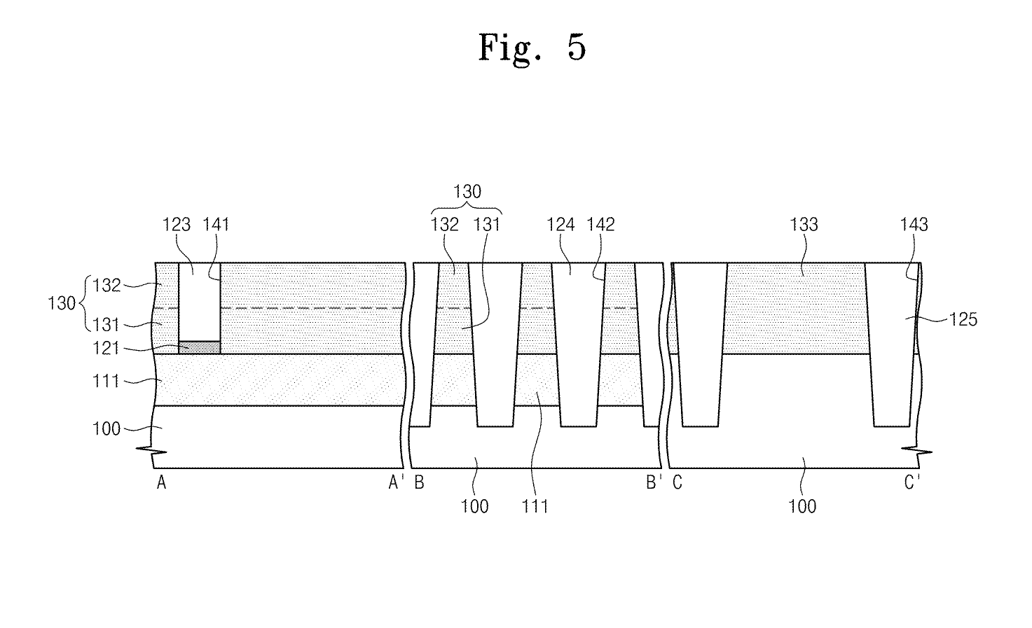

Referring to FIGS. 2 and 5, a first insulation layer 123 is formed in the opening 141. The first insulation layer 123 may comprise silicon oxide or silicon oxynitride, for example.

Also, first trenches 142 are formed in the cell array region CR and second trenches 143 are formed in the peripheral circuit region PR by patterning the first and second epitaxial semiconductor layers 130 and 133. For example, the first and second epitaxial semiconductor layers 130 and 133 are dry etched to form the trenches 142 and 143. In this respect, the first and second trenches 142 and 143 may be formed simultaneously, i.e., by the same etching process. Depending on the depths of the trenches and the characteristics of the etching process, the trenches may have inclined sides as shown in the figures. However, the first trenches 142 and the second trenches 143 may have shapes different from those shown in the drawings.

Moreover, the trenches 142 and 143 are formed so as to be elongated, i.e., so as to extend longitudinally, in a first direction (the Y-direction in FIG. 2). As a result, the first epitaxial semiconductor layer 130 has the shape of a series of stripes extending in the Y-direction.

The first trenches 142 are formed at least to the level of the substrate such that the first impurity region 110 is divided into first conductive lines 111. The first conductive lines 111 may be word lines in the finalized device. In any case, the first conductive lines 111 thus extend in the Y-direction and are spaced from each other in a second direction orthogonal to the first direction (the X-direction in FIG. 2).

On the other hand, the second trenches 143 extend through the second epitaxial semiconductor layer 133 and into the substrate 100. Thus, the second trenches 143 define an active region in the second epitaxial semiconductor layer 133.

Next, the first trenches 142 are filled with a first insulating layer 124 and the second trenches 143 are filled with second insulating layer 125. The first and second insulating layers 124 and 125 may be formed simultaneously. In this respect, these features may be formed by a Shallow Trench Isolation (STI) technique. For example, insulating material (not shown), such as silicon oxide, may be deposited on the substrate 100 to such a thickness as to overfill the first and second trenches 142 and 143, and then the resulting layer of insulating material may be planarized until the epitaxial semiconductor layers 130 and 133 are exposed. In this example, the deposition process is preferably a high-density plasma chemical vapor deposition process having an excellent gap-fill characteristic.

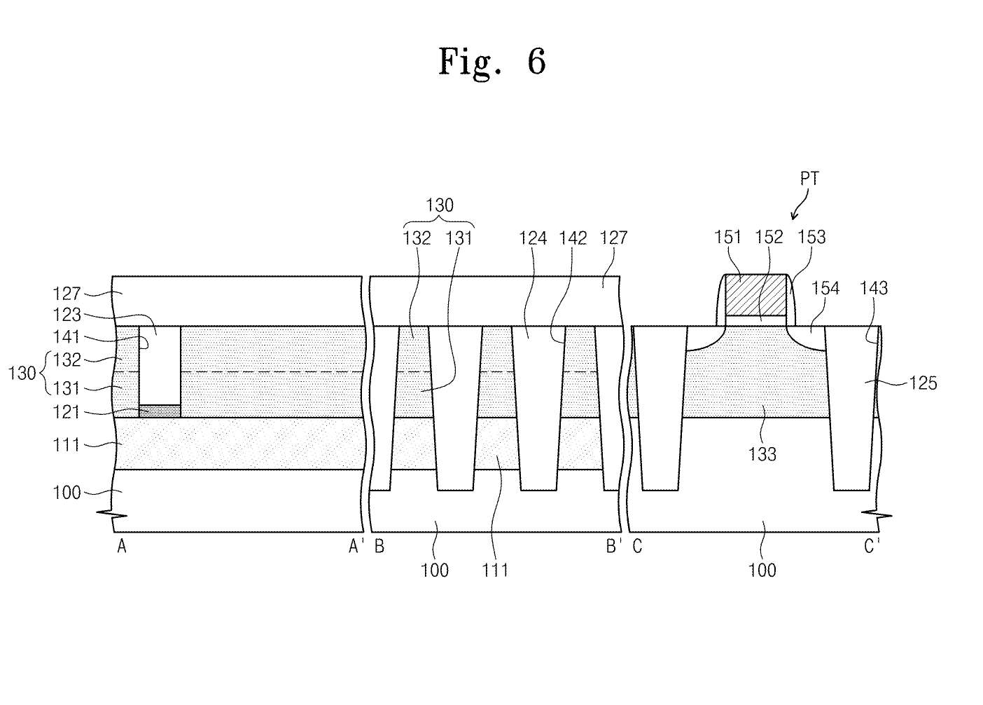

Referring to FIGS. 2 and 6, a first mask layer 127 is formed on the substrate to cover the cell array region CT. Then a peripheral transistor PT is formed on the second epitaxial semiconductor layer 133, by techniques that are known per se, while the cell array region CT is protected by a first mask layer 127. During the process of forming the peripheral transistor PT, certain layers are formed on the first mask layer 127 but these layers are not shown in the drawings for the sake of clarity.

The peripheral transistor PT includes a gate insulation layer 152 contacting the second epitaxial semiconductor layer 133, a gate electrode 151 on the gate insulation layer 152, and a source/drain region 154 adjacent to the gate electrode 151. A spacer 153 may be formed on sidewalls of the gate electrode 151. The gate insulation layer 152 is a thermal oxide layer, for example. The gate electrode 151 comprises conductive material such as a doped semiconductor, a metal, or a conductive metal nitride. The spacer 153 may include at least one of a silicon oxide layer, a silicon nitride layer, and a silicon oxynitride layer.

The source/drain region 154 may be formed in the second epitaxial semiconductor layer 133. Preferably, the bottom F2 of the source/drain region 154 is disposed at a level higher than that of the top surface F1 of the first conductive lines 111. If the peripheral transistor PT is an NMOS, the source/drain region 154 is an n-type impurity region formed in the second epitaxial semiconductor layer 133.

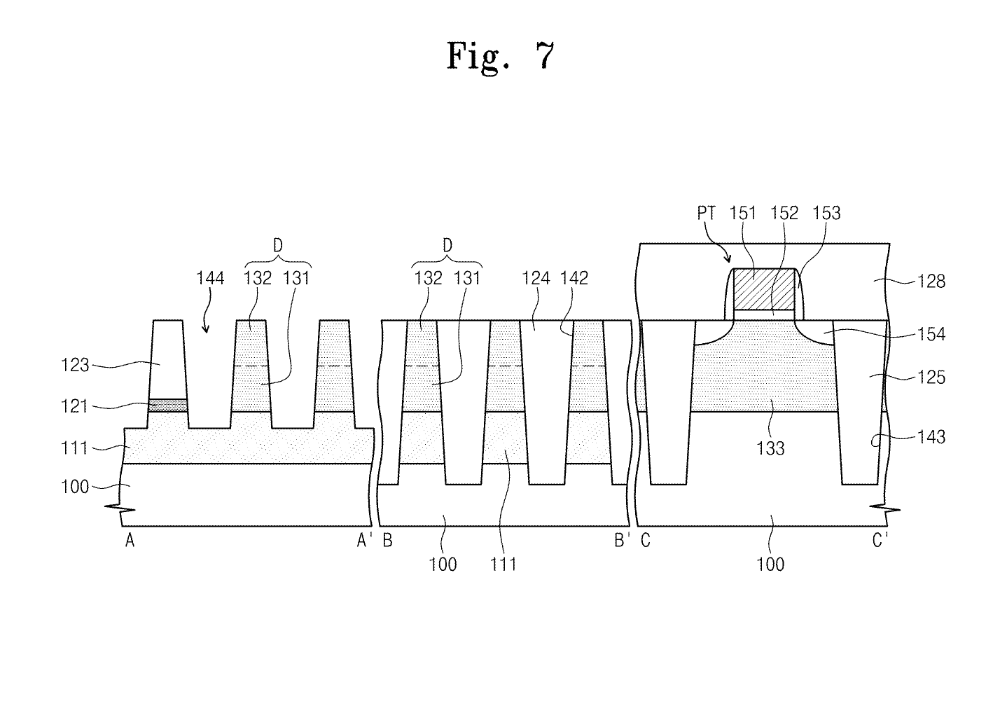

Referring to FIGS. 2 and 7, a first interlayer insulation layer 128 is then formed on the peripheral circuit region PR including over the peripheral transistor PT. The first interlayer insulation layer 128 may comprise silicon oxide or silicon oxynitride. In the subsequent processes that take place on the cell array region CT, certain layers may be formed on the first interlayer insulation layer 128 but these layers will not be shown in the drawings for the sake of clarity.

The first mask layer 127 is removed. Third trenches 144 are then formed by patterning (etching) the first epitaxial semiconductor layer 130. The third trenches 144 are elongated in a second direction (the X-direction in FIG. 2) that crosses the first direction. As a result, sidewalls of the etch stop layer 121 are exposed.

As another result, a two-dimensional array of diodes D is formed on the cell array region CR. That is, columns of the diodes D in the X-direction and rows of the diodes D in the Y-direction are formed. In this embodiment, the top surfaces of the diodes D are substantially coplanar with the top surface of the second epitaxial semiconductor layer 133.

Furthermore, upper portions of the first conductive lines 111 are etched by the process of forming the third trenches 144. That is, the first conductive lines 111 are not divided in the Y-direction by the process of patterning the first epitaxial semiconductor layer 130.

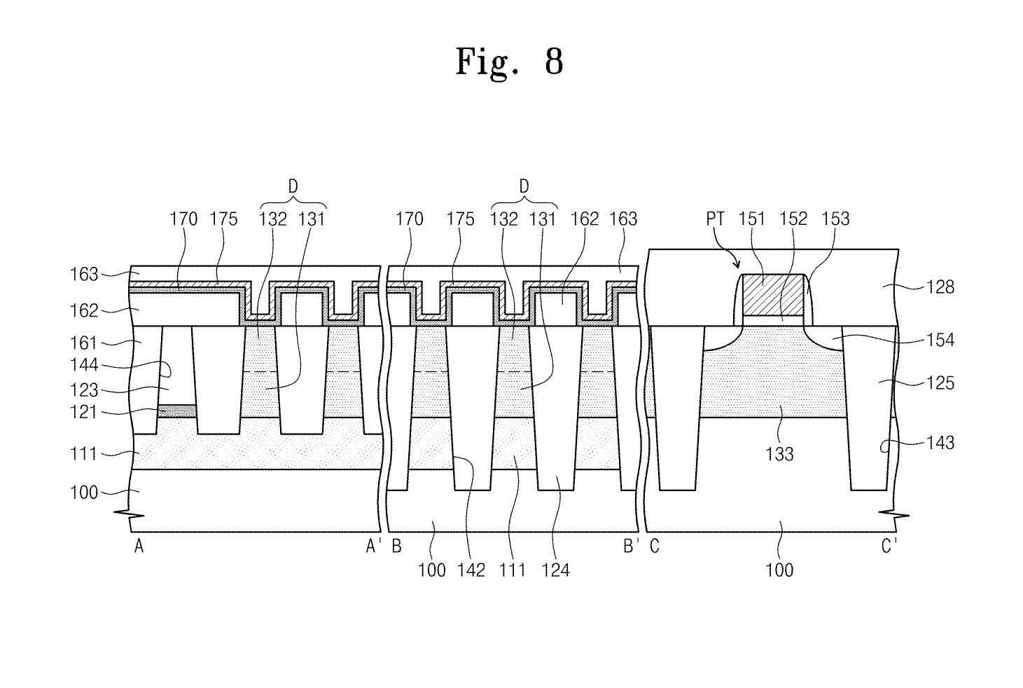

Referring to FIGS. 2 and 8, a second interlayer insulation layer 162 that exposes the diodes D is formed on the substrate 100. Then a silicide layer 170, a lower electrode layer 175, and a second insulation layer 163 are sequentially formed on the diodes D exposed by the second interlayer insulation layer 162. The lower electrode layer 175 may be formed of at least one of a transition metal, a conductive transition metal nitride, and a conductive ternary nitride. The second insulation layer 163 may be a silicon nitride layer, a silicon oxide layer, or a silicon oxynitride layer. The lower electrode layer 175 and the second insulation layer 163 may be formed through sputtering or chemical vapor deposition (CVD). The silicide layer 170 may be formed of a metal silicide such as a cobalt silicide, a nickel silicide, or a titanium silicide. The silicide layer 170 serves to reduce contact resistance between the diodes D and the lower electrode layer 175.

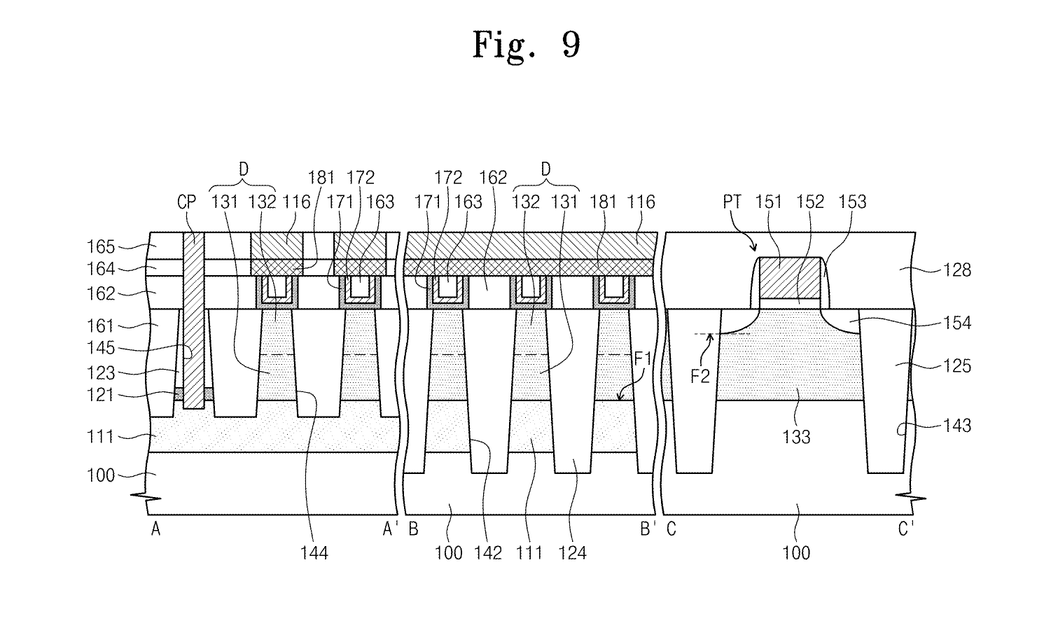

Referring to FIGS. 2 and 9, a planarization process is performed on the resulting structure to form a silicide pattern 171 and lower electrode pattern 172 on each of the diodes D. The silicide pattern 171, the lower electrode pattern 172, and respective segment of the second insulation layer 163 constitute a lower electrode structure. Variable resistance patterns 181 are then formed on the lower electrode patterns 172. The variable resistance patterns 181 are elongated in the X-direction and thus each contact the lower electrode patterns disposed on a respective column of the diodes D. The variable resistance patterns 181 in this example, as was mentioned at the beginning of the detailed description, are of phase change material. However, as was also mentioned, the inventive concept is not limited to the use of phase change material and thus the inventive concept is applicable to other forms of memory devices, e.g., MRAMs and FRAMs.

The variable resistance patterns 181 may be formed by first forming, on the substrate 100, a patterned third interlayer insulation layer 164 having openings that expose the lower electrode patterns 172. The third interlayer insulation layer 164 may comprise silicon oxide or silicon oxynitride. Then the openings in the patterned third interlayer insulation layer 164 are filled with a layer of phase change material. In this example, the phase change material is a layer of material comprising at least one of chalcogenide-based elements such as Te and Se, and a compound including at least one of Ge, Sb, Bi, Pb, Sn, Ag, As, S, Si, P, O, and C.

Next, second conductive lines 116 are formed on the variable resistance patterns 181, respectively. In particular, the second conductive lines 116 are formed so as to extend longitudinally in a direction that crosses the first conductive lines 111 and so as to be electrically connected to the diodes D via the variable resistance patterns 181 and lower electrode structures. For example, a patterned fourth interlayer insulation layer 165 comprising silicon oxide or silicon oxynitride, for example, is formed on the substrate 100. Then openings in the patterned fourth interlayer insulation layer 165 are filled with at least one of a transition metal, a conductive transition metal nitride, and a conductive ternary nitride to form the second conductive lines 116. The second conductive lines 116 may serve as bit lines in the finalized device. Also note, an upper electrode (not shown) may be provided between the second conductive lines 116 and the variable resistance pattern 181. The third and fourth interlayer insulation layers 164 and 165 may include a silicon oxide or a silicon oxynitride.

In addition, a contact plug CP is formed as electrically connected to each first conductive line 111. More specifically, a contact hole 145 is formed through the first insulation layer 123 and the second to fourth interlayer insulation layers 162, 164, and 165, and through the etch stop layer 121 to expose the conductive line 111. Then the contact hole 145 is filled with conductive material such as a doped semiconductor, a metal, or a conductive metal nitride.

As shown in FIG. 9, the variable resistance memory device according to the inventive concept includes a peripheral transistor PT in which the source/drain region 154 of the transistor PT is provided in the second epitaxial semiconductor layer 133. Although the second epitaxial layer 133 has the same crystalline structure as the substrate 100, the second epitaxial semiconductor layer 133 has fewer crystal defects than the substrate 100. That is, the epitaxial process (i.e., a high-temperature process) in effect reduces the number of crystal defects of the substrate 100 as the epitaxial overlayer is grown.

Furthermore, components of the peripheral transistor PT are formed after the high temperature epitaxial process for forming the diodes D is performed. Therefore, the characteristics of the peripheral transistor PT are not degraded by the process of forming the diodes D.

Accordingly, the peripheral transistor PT has improved electrical characteristics.

Still further, the second epitaxial semiconductor layer 133 may be formed together with the diodes D of the cell array region CR. That is, the second epitaxial semiconductor layer 133 may be formed by the same epitaxial process used to form the diodes D. Additionally, the second insulating layer 125 for defining an active region on the second epitaxial semiconductor layer 133 and the first insulating layer 124 for forming the diodes D can be formed simultaneously. Therefore, the process of manufacturing a variable resistance memory device according to the inventive concept is relatively simple.

A second embodiment of a variable resistance memory device and a method of manufacturing the same according to the inventive concept will now be described with reference to FIGS. 2 and 10 through 14. However, a detailed description of features and aspects of this embodiment which are similar to those of the embodiment of FIGS. 3-9 may be omitted for the sake of brevity.

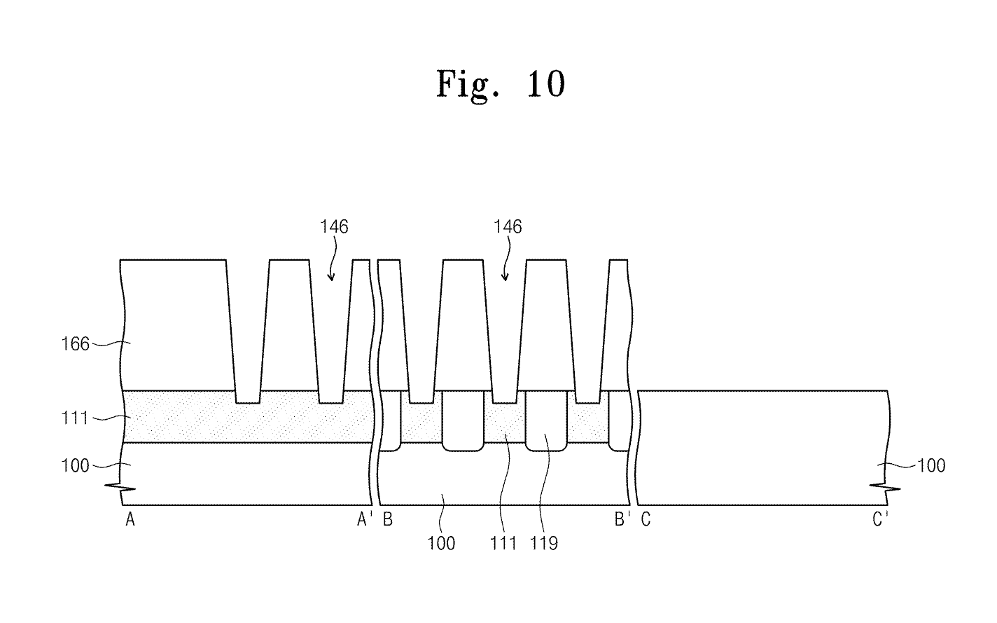

Referring to FIGS. 2 and 10, a substrate 100 including a cell array region CR and a peripheral circuit region PR is provided. First conductive lines 111 are formed in the cell array region CR. In this embodiment, the first conductive lines 111 are formed in the substrate 100 by implanting impurity ions, having a conductive of a type different from that of the substrate 100, into regions of the substrate that are elongated in the first direction. As an example of this process, a first impurity region (not shown) is formed by implanting n-type impurity ions into the substrate 100, forming shallow trenches in the first impurity region, and filling the trenches with an insulating layer 119 to divide the impurity region into the first conductive lines 111 (extending in the Y-direction in FIG. 2). In another example, the first conductive lines 111 may be formed by patterning the substrate 100 to form trenches therein, and filling the trenches with a metallic layer.

An interlayer insulation layer 166 including a two-dimensional array of second openings 146 is formed on the resulting structure by deposition and etching, e.g., dry-etching, processes. The second openings 146 expose the first conductive lines 111. Upper portions of the first conductive lines 111 may be etched during the forming of the second openings 146. Depending on the depths of the second openings 146 and the characteristics of the etching process used to form the second openings 146, the second openings 146 may have inclined sides as shown in the figure.

Furthermore, in this process, the first conductive lines 111 and the interlayer insulation layer 166 are not formed on the peripheral circuit region PR. In this respect, a mask (not shown) may be formed on the peripheral circuit region PR before the first conductive lines 111 and the fifth interlayer insulation layer 166 are formed.

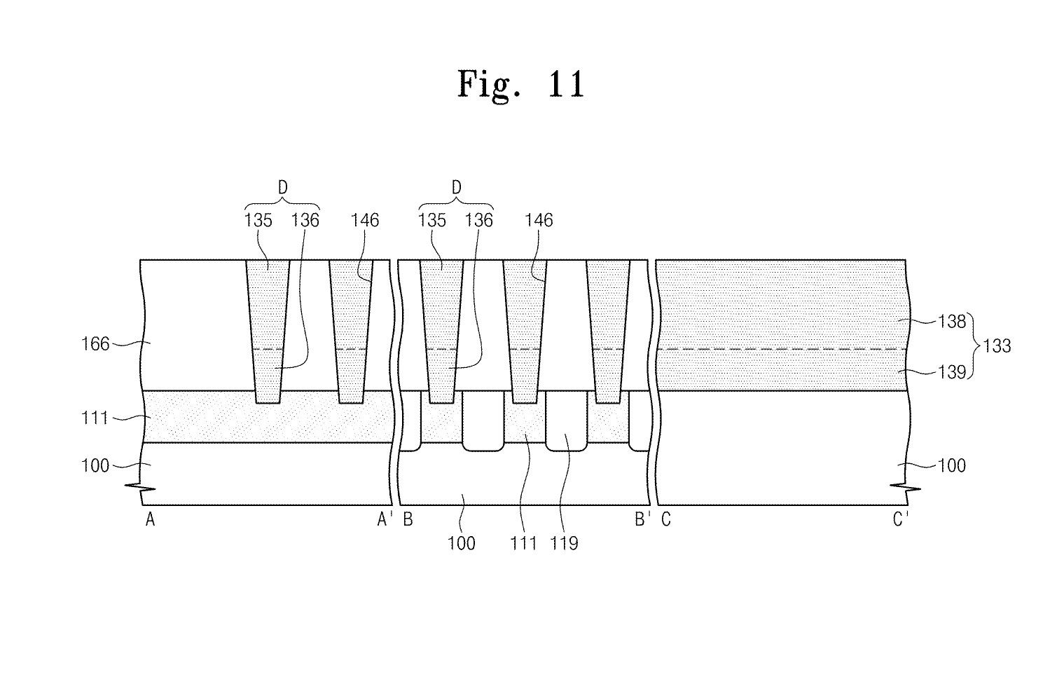

Referring to FIGS. 2 and 11, diodes D are formed in the second openings 146 through a selective epitaxial process. Also, a second epitaxial semiconductor layer 133 may be formed on the peripheral circuit region PR through the selective epitaxial process.

The diodes D are formed by forming a first lower impurity region 136 and a first upper impurity region 135 of different conductivity types in the second openings 146, with the first lower impurity region 136 having a different type of conductivity than the substrate 100 and the first upper impurity region 135 having the same type of conductivity as the substrate 100. The first upper and lower impurity regions 135 and 136 may be formed using an ion implantation process or an in-situ doping process.

The ion implantation process or in-situ doping process for forming the first upper and lower impurity regions 135 and 136 may be simultaneously performed on the peripheral circuit region PR. For example, p-type impurities may be simultaneously implanted into an epitaxial layer on the cell array region CR and the peripheral circuit region PR to form upper impurity region 135 and second upper impurity region 138.

The first lower impurity region 136 and a second lower impurity region 139 in the second epitaxial semiconductor layer 133 may also be formed simultaneously such that the second lower impurity region 139 has the same type of conductivity as the first lower impurity region 136. Alternatively, the lower part of the second epitaxial semiconductor layer 133 may be left as is, i.e., in its intrinsic epitaxial state.

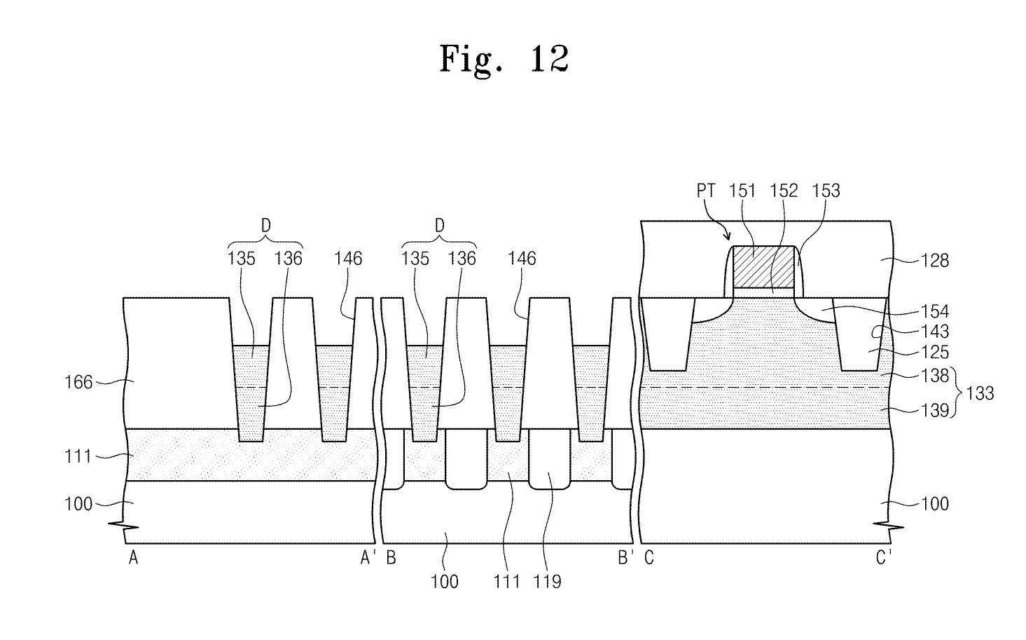

Referring to FIG. 12, second trenches 143 are formed in the second epitaxial semiconductor layer 133, and the second trenches are filled with a second insulating layer 125 to define an active region of the peripheral circuit region. The bottom surface of the second insulating layer 125 is located at a level above that of the top of the second lower impurity region 139, and preferably above that of the top surface of the first conductive lines 111.

A peripheral transistor PT is then formed in the peripheral circuit region PR. The peripheral transistor PT includes a gate insulation layer 152 contacting the second epitaxial semiconductor layer 133, a gate electrode 151 on the gate insulation layer 152, and a source/drain region 154 adjacent to the gate electrode 151. A spacer 153 may be formed on sidewalls of the gate electrode 151. The source/drain region 154 is formed in the second epitaxial semiconductor layer 133. For example, if the peripheral transistor PT is an NMOS, an n-type impurity region is formed in the second epitaxial semiconductor layer 133 as the source/drain region 154. Then an interlayer insulation layer 128 is formed on the peripheral circuit region PR over the peripheral transistor PT.

Next, upper portions of the diodes D are removed to expose upper parts of the inner surfaces of the interlayer insulating layer 166 which delimit the sides of the second openings 146. The upper portions of the diodes D may be removed through a selective etching process. Accordingly, the top surface of the second epitaxial semiconductor layer 133 may become located at a level above that of the top surfaces of the diodes D.

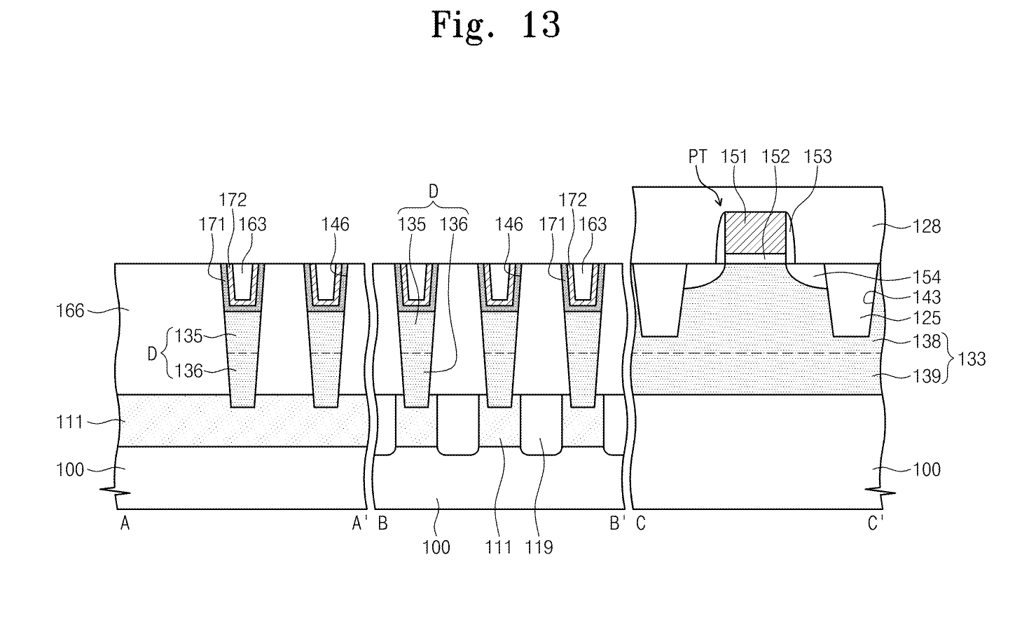

Referring to FIG. 13, silicide patterns 171, lower electrode patterns 172, and second insulation layer segments 163 are formed in the second openings 146. The silicide patterns 171, lower electrode patterns 172, and second insulation layer segments 163 constitute lower electrode structures formed on the diodes D, respectively.

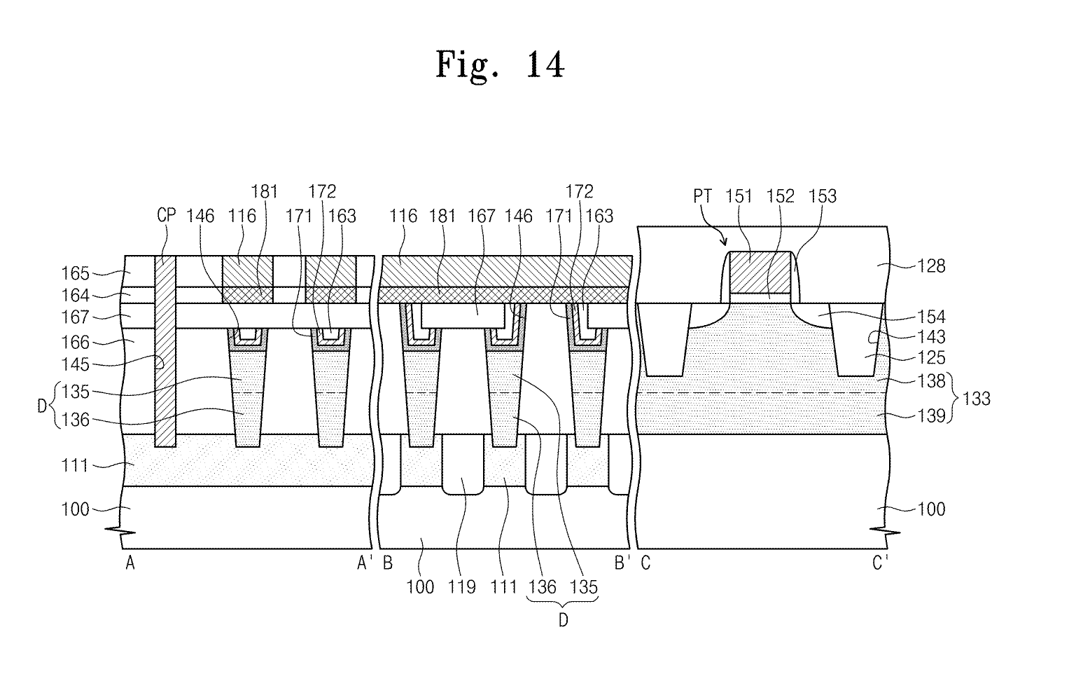

Referring to FIG. 14, a portion of each lower electrode structure, including that of its lower electrode pattern 172, is removed. Then, third insulation layer patterns 167 are formed. Each third insulation layer patterns 167 may be elongated in the X-direction. On the other hand, with respect to its widthwise direction, each third insulation layer pattern 167 laterally spans and extends into adjacent ones lower electrode structures atop portions of the lower electrode patterns 172 thereof.

Next, a third interlayer insulation layer 164 exposing the lower electrode structures and the third insulation layer patterns 167 is formed on the substrate 100 in the cell array region CR. Then variable resistance patterns 181 are formed in the third interlayer insulation layer 164. The variable resistance patterns 181 are elongated in the X-direction. The variable resistance patterns 181 may be of phase change material. In this respect, refer to the descriptions above.

In this embodiment, the variable resistance patterns 181 are prevented from contacting the entirety of the lower electrode patterns 172 by the third insulation layer patterns 167. That is, the contact area between each lower electrode pattern 172 and the overlying variable resistance pattern 181 is in effect reduced by a third insulation layer pattern 167. Accordingly, a reset current Ireset is in effect reduced.

Next, second conductive lines 116 are formed on the variable resistance patterns 181 in a manner similar to that shown in and described with reference to FIG. 9. Likewise, as was also mentioned above, an upper electrode (not shown) may be provided between the second conductive lines 116 and the variable resistance patterns 181. In any case, the second conductive lines 116 are electrically connected to the variable resistance patterns 181.

In addition, a contact plug CP is formed as electrically connected to each first conductive line 111. More specifically, a contact hole 145 is formed through the interlayer insulation layers 166, 167, 164 and 165 to expose the conductive line 111. Then the contact hole 145 is filled with conductive material such as a doped semiconductor, a metal, or a conductive metal nitride.

In this embodiment as well, as shown in FIG. 14, the variable resistance memory device includes a peripheral transistor PT in which the source/drain region 154 of the transistor PT is provided in the second epitaxial semiconductor layer 133. Likewise, components of the peripheral transistor PT are formed after the high temperature epitaxial process for forming the diodes D is performed. Accordingly, the peripheral transistor PT has improved electrical characteristics.

And like the previously described embodiment, the second epitaxial semiconductor layer 133 may be formed together with the diodes D of the cell array region CR. That is, the second epitaxial semiconductor layer 133 may be formed by the same epitaxial process used to form the diodes D. Therefore, this embodiment of a method of manufacturing a variable resistance memory device is also relatively simple.

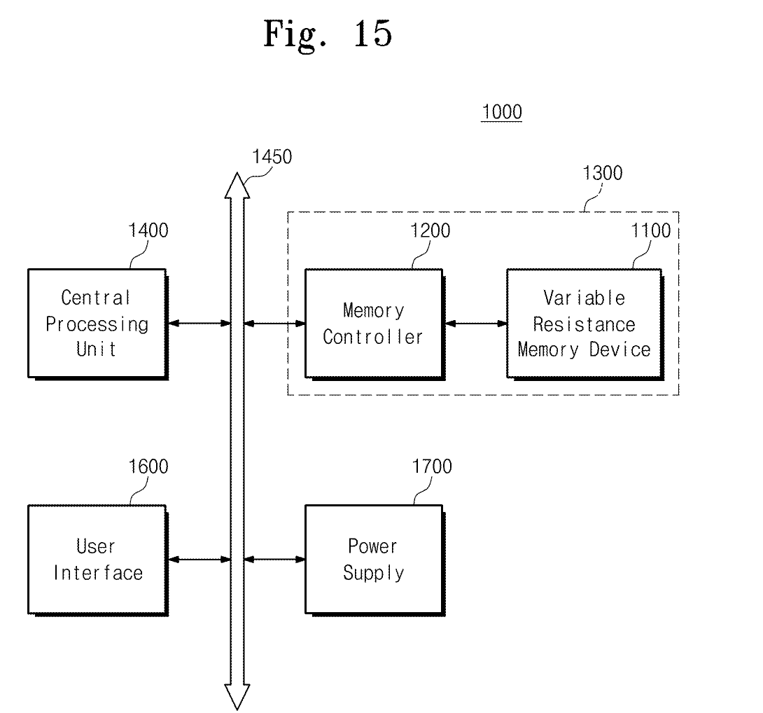

A memory system that employs a variable resistance memory device according to the inventive concept will now be described with reference to FIG. 15.

Referring to FIG. 15, the memory system 1000 includes a semiconductor memory device 1300, a central processing unit (CPU) 1400, a user interface 1600, and a power supply 1700, which are electrically connected to a bus 1450. Also, although not shown in the drawings, the memory system 1000 may also have an application chipset, a camera image processor (CIS), or a mobile DRAM.

The semiconductor memory device 1300 includes a variable resistance memory device 1100 according to the inventive concept (i.e., of any of the types described above) and a memory controller 1200. The variable resistance memory device 1100 stores data provided through the user interface 1600 or data processed by the CPU 1400, as dictated by the memory controller 1200. The variable resistance memory device 1100 may be embodied as a solid state drive (SSD) so as to have a characteristically high write speed.

Additionally, the memory system 1000 may be employed as the memory system of a Personal Digital Assistant (PDA), a portable computer, a web tablet, a wireless phone, a mobile phone, a digital music player, a memory card, or any other known device for transmitting and receiving information in a wireless environment.

Furthermore, a variable resistance memory device or a memory system according to the inventive concept may be packaged in various ways. For example, the variable resistance memory device or memory system may be assembled as part of a Package on Package (PoP), Ball Grid Array (BGA) package, Chip Scale Package (CSP), Plastic Leaded Chip Carrier (PLCC), Plastic Dual In-Line Package (PDIP), Die in Waffle Pack, Die in Wafer Form, Chip On Board (COB) package, Ceramic Dual In-Line Package (CERDIP), Plastic Metric Quad Flat Pack (MQFP), Thin Quad Flat Pack (TQFP), Small Outline Integrated Circuit (SOIC) package, Shrink Small Outline Package (SSOP), Thin Small Outline Package (TSOP), System In Package (SIP), Multi-Chip Package (MCP), Wafer-level Fabricated Package (WFP), or Wafer-level Processed Stack Package (WSP).

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

1. A method of manufacturing a variable resistance memory device, comprising:
providing a substrate having a cell array region and a peripheral circuit region;
forming a semiconductor layer on the cell array region and the peripheral circuit region, wherein the forming of the semiconductor layer comprises an epitaxial process such that the semiconductor layer is an epitaxial semiconductor layer; and
forming, on the peripheral circuit region, a peripheral transistor constituted by part of the epitaxial semiconductor layer.

2. The method of claim 1, wherein the forming of the peripheral transistor comprises forming a source/drain region in the epitaxial semiconductor layer.

3. The method of claim 1, wherein the forming of the peripheral transistor comprises forming a gate insulation layer directly on the epitaxial semiconductor layer, and forming a gate electrode on the gate insulation layer.

4. The method of claim 1, further comprising forming diodes, Metal Oxide Semiconductor (MOS) transistors, or bipolar transistors as selecting devices, on the cell array region, wherein the forming of the selecting devices includes patterning the epitaxial semiconductor layer.

5. The method of claim 4, wherein the patterning of the epitaxial semiconductor layer comprises a first patterning process of forming first trenches, elongated in a first direction, in the epitaxial semiconductor layer on both the cell array region and the peripheral circuit region, wherein the first trenches in the epitaxial semiconductor on the peripheral circuit region delimit an active region, and
a second patterning process of forming second trenches, elongated in a direction that crosses the first direction, in the epitaxial semiconductor on the cell array region.

6. The method of claim 5, further comprising forming a first region of impurities in the substrate before the selecting devices are formed, and wherein the first region of impurities is divided into a plurality of conductive lines by the first patterning process.

7. The method of claim 4, further comprising forming an etch stop layer on the substrate before the epitaxial semiconductor layer is formed.

8. The method of claim 4, wherein the forming of the epitaxial semiconductor layer on the cell array region and the peripheral circuit region comprises forming an epitaxial layer and implanting impurity ions of the same conductivity type as the substrate in the epitaxial layer.

9. The method of claim 1, further comprising forming an interlayer insulation layer on the cell array region of the substrate, and forming openings in the interlayer insulation layer that expose portions of the substrate, respectively, and
wherein the epitaxial process comprises growing crystalline structures on the portions of the substrate exposed by the openings in the interlayer insulation layer.

10. A method of manufacturing a variable resistance memory device, comprising:
providing a substrate having a cell array region and a peripheral circuit region;
forming structures of semiconductor material on the cell array region and forming an active region of semiconductor material on the peripheral circuit region, including by epitaxially growing crystalline material simultaneously on the cell array region and the peripheral circuit region;
forming variable resistor elements on the structures of semiconductor material on the cell array region, respectively; and
forming a peripheral transistor at the active region.

11. The method of claim 10, wherein the forming of the peripheral transistor comprises forming a gate electrode on the crystalline material epitaxially grown on the peripheral circuit region, and doping the active region with impurities to form a source/drain region in the crystalline material epitaxially grown on the peripheral circuit region.

12. The method of claim 10, wherein the forming of structures of semiconductor material on the cell array region comprises forming diodes on the cell array region.

13. The method of claim 10, wherein the forming of structures of semiconductor material on the cell array region and the forming of the active region of semiconductor material on the peripheral circuit region comprises epitaxially growing a blanket layer of crystalline material simultaneously on the cell array region and the peripheral circuit region, and then simultaneously forming trenches in the blanket layer in both the cell array region and the peripheral circuit region.

14. The method of claim 10, wherein the forming of structures of semiconductor material on the cell array region further comprises forming an interlayer insulation layer on the cell array region, and forming openings in the interlayer insulation layer that expose portions of the substrate, respectively, and
wherein the crystalline material is epitaxially grown on the portions of the substrate exposed by the openings in the interlayer insulation layer.

15-20. (canceled)
